(19) United States
(12) Patent Application Publication
(10) Pub. No.: US 2024/0243707 A1
(43) Pub. Date: Jul. 18, 2024

(54) OVER VOLTAGE PROTECTION CIRCUIT AND POWER AMPLIFIER INCLUDING THE SAME

(71) Applicant: SAMSUNG ELECTRO-MECHANICS CO., LTD., Suwon-si (KR)

(72) Inventors: Yoshiyuki TONAMI, Suwon-si (KR); Geunyong LEE, Suwon-si (KR); Kyujin CHOI, Suwon-si (KR); Seungchul PYO, Suwon-si (KR); Suyeon HAN, Suwon-si (KR); Kyung Hee HONG, Suwon-si (KR)

(73) Assignee: SAMSUNG ELECTRO-MECHANICS CO., LTD., Suwon-si (KR)

(21) Appl. No.: 18/321,682

(22) Filed: May 22, 2023

(30) Foreign Application Priority Data
Jan. 18, 2023 (KR) 10-2023-0007580

(51) Int. Cl. H03F 3/24; H03F 1/52

(52) U.S. Cl. CPC H03F 3/245; H03F 1/52; H03F 2200/222; H03F 2200/294

(57) ABSTRACT

An over voltage protection circuit protecting a power amplifier amplifying an input radio frequency (RF) signal by receiving a bias current from a bias circuit. The circuit includes an input signal detector detecting a magnitude of the input RF signal, and a first transistor receiving the magnitude of the input RF signal through a control terminal thereof and turned on based on the magnitude of the input RF signal to sink the current from a first node of a bias circuit.

### CROSS-REFERENCE TO RELATED APPLICATIONS

This application claims the benefit under 35 USC 119(a) of Korean Patent Application No. 10-2023-0007580 filed on Jan. 18, 2023, in the Korean Intellectual Property Office, the entire disclosure of which is incorporated herein by reference for all purposes.

### BACKGROUND

### 1. Field

The present disclosure relates to an over voltage protection circuit and a power amplifier including the same.

### 2. Description of the Background

A transmitter used in a wireless communication system may include a power amplifier amplifying a radio frequency (RF) signal to increase a transmission distance.

The power amplifier may be expected to have high reliability. There may be an objective that the power amplifier should not be damaged under an absolute maximum rate (AMR) condition.

An overcurrent exceeding a limit of the power amplifier may flow under the condition that an input signal of the maximum power may be applied to the power amplifier, and a case may thus occur in which an element of the power amplifier may be damaged. An over voltage protection circuit may thus be desired to protect the power amplifier.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an over voltage protection circuit protecting a power amplifier amplifying an input radio frequency (RF) signal by receiving a bias current from a bias circuit, includes an input signal detector detecting a magnitude of the input RF signal, and a first transistor receiving the magnitude of the input RF signal through a control terminal thereof and turned on based on the magnitude of the input RF signal to sink the current from a first node of the bias circuit.

The bias circuit may include a second transistor and a third transistor stacked between a current source supplying a reference current and the ground, and a fourth transistor having a control terminal connected to the current source and supplying the bias current, and the first node may be a junction between the second transistor and the third transistor.

The bias circuit may include a second transistor supplying the bias current, and the first node may be a control terminal of the second transistor.

The input signal detector may include a first resistor adjusting a turn-on voltage level of the first transistor based on the magnitude of the input RF signal.

The input signal detector may further include a capacitor having one end into which the input RF signal is input, a diode connected between the other end of the capacitor and one end of the first resistor, and a second resistor connected between one end of the first resistor and the ground, and the other end of the first resistor may be connected to the control terminal of the first transistor.

The magnitude of the input RF signal may correspond to an envelope of the input RF signal.

The power amplifier may include a power transistor amplifying and outputting a voltage of the input RF signal, and the bias circuit may supply the bias current to the power transistor.

The power amplifier may include a driver transistor receiving a first bias current and amplifying a voltage of the input RF signal, and a power transistor receiving a second bias current and amplifying an output RF signal of the driver transistor, the bias circuit may include a first bias circuit supplying the first bias current, and a second bias circuit supplying the second bias current, and the first transistor may be turned on based on the magnitude of the input RF signal to sink the current from at least one of a first node of the first bias circuit and a first node of the second bias circuit.

The first bias circuit may include a second transistor and a third transistor stacked between a current source supplying a reference current and the ground, and a fourth transistor having a control terminal connected to the current source and supplying the first bias current, the second bias circuit may include a fifth transistor and a sixth transistor stacked between a current source supplying the reference current and the ground, and a seventh transistor having a control terminal connected to the current source and supplying the first bias current. The first node of the first bias circuit may be a junction between the second transistor and the third transistor, the first node of the second bias circuit may be a junction between the fifth transistor and the sixth transistor, and a first terminal of the first transistor may be connected to at least one of the first node of the first bias circuit and the first node of the second bias circuit, and a second terminal of the first transistor may be connected to the ground.

The first bias circuit may include a second transistor supplying the first bias current, and the second bias circuit may include a third transistor supplying the second bias current. The first node of the first bias circuit may be a control terminal of the second transistor, the first node of the second bias circuit may be a control terminal of the third transistor, and a first terminal of the first transistor may be connected to at least one of the first node of the first bias circuit and the first node of the second bias circuit, and a second terminal of the first transistor may be connected to the ground.

In another general aspect, a power amplifier includes a first transistor amplifying a radio frequency (RF) signal, a first bias circuit supplying a first bias current to the first transistor, and an over voltage protection circuit detecting a magnitude of the input RF signal and decreasing the first bias current by sinking the current from the first bias circuit when the magnitude of the input RF signal is a set value or more.

The over voltage protection circuit may include an input signal detector detecting the magnitude of the input RF signal, and a second transistor receiving the magnitude of the input RF signal through a control terminal thereof and sinking the current from the first bias circuit when turned on.

The first bias circuit may include a third transistor and a fourth transistor stacked between a current source supplying a reference current and the ground, and a fifth transistor having a control terminal connected to the current source and supplying the first bias current, and a first terminal of the second transistor may be connected to a junction between the third transistor and the fourth transistor, and a second terminal of the second transistor may be connected to the ground.

The first bias circuit may include a third transistor supplying the first bias current, and a first terminal of the second transistor may be connected to a control terminal of the third transistor, and a second terminal of the second transistor may be connected to the ground.

The power amplifier may further include a third transistor amplifying an output RF signal of the first transistor, and a second bias circuit supplying a second bias current to the third transistor.

The over voltage protection circuit may sink the current from the second bias circuit when the magnitude of the input RF signal is the set value or more.

The magnitude of the input RF signal may correspond to an envelope of the input RF signal.

In another general aspect, a power amplifier includes one or more transistors configured to amplify an input radio frequency (RF) signal and to each receive a bias current of one or more bias currents, and an over voltage protection circuit configured to detect a magnitude of the input RF signal and to decrease at least one of the one or more bias currents in response to the detected magnitude of the input RF signal.

The power amplifier may further include one or more bias circuits configured to supply the one or more bias currents, wherein the over voltage protection circuit may be further configured to sink the bias current from the one or more bias circuits to decrease the at least one of the one or more bias currents.

The over voltage protection circuit may include a sink transistor configured to turn on to decrease the at least one of the one or more bias currents, and a resistor configured to adjust a turn on voltage of the sink transistor.

Other features and aspects will be apparent from the following detailed description, the drawings, and the claims.

### BRIEF DESCRIPTION OF THE DRAWINGS

FIG. 1 is a view showing a power amplifier 1000a according to an embodiment.

FIG. 2 is a view showing a multi-stage power amplifier 1000b according to another embodiment.

FIG. 3 is a view showing a power amplifier 1000c according to still another embodiment.

FIG. 4 is a view showing a power amplifier 1000d according to yet another embodiment.

FIG. 5 is a view showing an example of a bias circuit 200 shown in FIG. 1.

FIG. 6 is a view showing an example of an over voltage protection circuit 300a shown in FIG. 1.

FIG. 7 is a view showing examples of a bias circuit 500 and an over voltage protection circuit 300b shown in FIG. 2.

FIG. 8 is a view showing simulation results of a base voltage of a sink transistor Q5 and power of an input RF signal, shown in FIG. 7.

FIG. 9 is a view showing simulation results of a collector voltage of a transistor Q10 and the power of the input RF signal shown in FIG. 7.

FIG. 10 is a view showing simulation results of the input RF signal RFIN and output RF signal RFOUT of the multi-stage power amplifier shown in FIG. 2.

FIG. 11 is a view showing the over voltage protection circuit 300d shown in FIG. 4.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION OF THE EMBODIMENTS

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element is referred to as being “coupled to” another element, it may not only indicate that the element and another element are “directly or physically coupled to” each other, but also indicate that the element and another element are “indirectly or contactlessly coupled to” each other while having still another element interposed therebetween.

Throughout the specification, when an element is referred to as being “connected to” another element, it may not only indicate that the element and another element are “directly or physically connected to” each other, but also indicate that the element and another element are “indirectly or contactlessly connected to” each other while having still another element interposed therebetween or the element and another element are “electrically connected to” each other.

In contrast, when an element is described as being “directly on,” “directly connected to,” or “directly coupled to” another element, there can be no other elements intervening therebetween.

Throughout the specification, a radio frequency (RF) signal may have formats based on protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the abovementioned protocols, and is not limited thereto.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

One or more embodiments of the disclosure may provide an over voltage protection circuit that may protect a power amplifier. At least one of the embodiments may provide a power amplifier including an over voltage protection circuit.

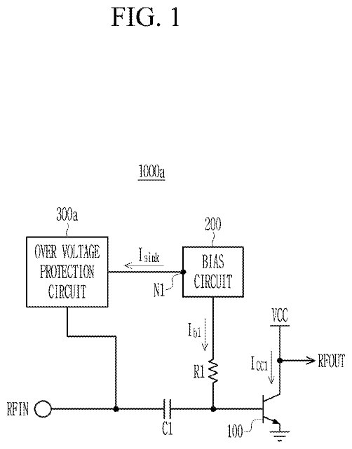

FIG. 1 is a view showing a power amplifier 1000a according to an embodiment.

Referring to FIG. 1, the power amplifier 1000a may include a power transistor 100, a bias circuit 200, and an over voltage protection circuit 300a.

The power transistor 100 may amplify power of an RF signal RFIN input to an input terminal (i.e., base) and then output the amplified power to an output terminal (i.e., collector). That is, the base of the power transistor 100 may receive the RF signal RFIN, and the collector of the power transistor 100 may output the amplified RF signal RFOUT. An emitter of the power transistor 100 may be connected to the ground, and although not shown in FIG. 1, a resistor may be additionally connected between the emitter of the power transistor 100 and the ground. In addition, the collector of the power transistor 100 may be connected to a power supply voltage VCC, and the power transistor 100 may be operated by the power supply voltage VCC.

The power transistor 100 may be implemented as various transistors such as a heterojunction bipolar transistor HBT, a bipolar junction transistor BJT, and an insulated gate bipolar transistor IGBT. In addition, FIG. 1 shows that the power transistor 100 is an n-type, which may be replaced by a p-type. Meanwhile, the base of the transistor may serve as a control terminal, and thus be referred to as a “control terminal.”

The collector of the transistor may be one terminal of the transistor, and thus be referred to as a “first terminal” or a “second terminal.”

In addition, the emitter of the transistor may also be one terminal of the transistor, and thus be referred to as the “first terminal” or the “second terminal.”

A coupling capacitor C1 may be connected to the input terminal (i.e., base) of the power transistor 100. The coupling capacitor C1 may perform a function of blocking a direct current (DC) component from the RF signal RFIN.

The bias circuit 200 may supply a bias current Ib1 for biasing the power transistor 100. The bias current Ib1 may be supplied to the base of the power transistor 100, and the power transistor 100 may set a bias level (or bias point) by the bias current Ib1. A resistor R1 may be connected between the bias circuit 200 and the base of the power transistor 100.

The bias current Ib1 may be decreased by the over voltage protection circuit 300a. A current I_{CC1} flowing through the output terminal (i.e., collector) of the power transistor 100 may be decreased when the bias current Ib1 is decreased. In FIG. 1, I_{CC1} represents the current flowing through the output terminal (i.e., collector) of the power transistor 100. Here, the current I_{CC1} may be an output current of the power amplifier 1000a.

The current flowing through the power amplifier 1000a may also be increased when the input RF signal RFIN is increased. In a specific situation, when power of the input RF signal RFIN is out of a normal operation range of the power amplifier 1000a, the current I_{CC1} may excessively flow in the power amplifier 1000a, thus exceeding a limit of the current that an element of the power amplifier 1000a may withstand.

The over voltage protection circuit 300a according to an embodiment may detect a voltage of the input RF signal RFIN and be operated when the detected voltage is a set value or more. The over voltage protection circuit 300a may be connected to a terminal N1 of the bias circuit 200 and may sink a current Iₛᵢₙₖ from the terminal N1 when the detected voltage is the set value or more. The bias current Ib1 may be varied by the current Iₛᵢₙₖ. For example, the bias current Ib1 may be decreased when the current Iₛᵢₙₖ is increased, and here, the current I_{CC1} flowing through the power transistor 100 may be decreased. The power transistor 100 may thus be protected from an over voltage state.

An input matching network may be connected to the input terminal (i.e., base) of the power transistor 100, and an output matching network may be connected to the output terminal (i.e., collector) of the power transistor 100. The input matching network may perform impedance matching between the input RF signal RFIN and the power transistor 100. The output matching network may perform impedance matching between the output RF signal RFOUT of the power transistor 100 and a load.

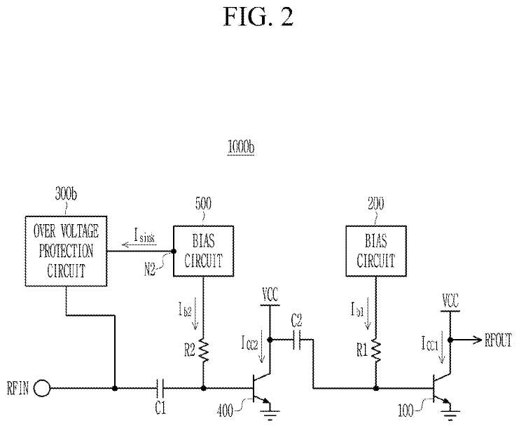

FIG. 2 is a view showing a multi-stage power amplifier 1000b according to another embodiment.

Referring to FIG. 2, the multi-stage power amplifier 1000b may represent an amplifier in which one-stage amplifiers are cascaded into several stages. The one-stage amplifier may include, for example, an amplifier including one power transistor 100 shown in FIG. 1. Here, each amplifier may be referred to as a stage. Although FIG. 2 shows a two-stage power amplifier, the power amplifier may have three or more stages.

The multi-stage power amplifier 1000b may include a transistor 400 of a first stage amplifier, a transistor 100 of a second stage amplifier, the bias circuit 200, a bias circuit 500, and an over voltage protection circuit 300b.

The first stage amplifier may be a driver amplifier (DA) which has a high gain and delivers an RF signal level suitable for the second stage amplifier. The first stage amplifier may include the transistor 400.

The second stage amplifier may be the power amplifier PA which may generate high output required by a system. The second stage amplifier may include the transistor 100.

In the multi-stage power amplifier 1000b, the transistor 400 of the first stage amplifier may be referred to as the driver transistor 400, and the transistor 100 of the second stage amplifier may be referred to as the power transistor 100.

The driver transistor 400 may amplify power of an RF signal RFIN input to an input terminal (i.e., base) and then output the same to an output terminal (i.e., collector). That is, the RF signal RFIN may be input to the base of the driver transistor 400, and the collector of the driver transistor 400 may output the amplified RF signal. An emitter of the driver transistor 400 may be connected to the ground, and although not shown in FIG. 1, a resistor may be additionally connected between the emitter of the driver transistor 400 and the ground. In addition, the collector of the driver transistor 400 may be connected to a power supply voltage VCC, and the driver transistor 400 may be operated by the power supply voltage VCC.

An output RF signal of the driver transistor 400 may be input to the input terminal (i.e., base) of the power transistor 100 via a capacitor C2. The capacitor C2 may perform a function of blocking a direct current (DC) component from the output RF signal of the driver transistor 400.

The power transistor 100 may amplify power of the RF signal input to the input terminal and then output the same to the output terminal (i.e., collector). That is, the base of the power transistor 100 may receive the RF signal to be amplified, and the collector of the power transistor 100 may output the amplified RF signal. An emitter of the power transistor 100 may be connected to the ground. A resistor may be additionally connected between the emitter of the power transistor 100 and the ground. In addition, the collector of the power transistor 100 may be connected to the power supply voltage VCC, and the power transistor 100 may be operated by the power supply voltage VCC.

The driver transistor 400 and the power transistor 100 may each be implemented as various transistors such as a heterojunction bipolar transistor HBT, a bipolar junction transistor BJT, and an insulated gate bipolar transistor IGBT.

The bias circuit 200 may supply a bias current Ib1 for biasing the power transistor 100. The bias current Ib1 may be supplied to the base of the power transistor 100, and the power transistor 100 may set a bias level (or bias point) by the bias current Ib1. A resistor R1 may be connected between the bias circuit 200 and the base of the power transistor 100.

The bias circuit 500 may supply a bias current Ib2 for biasing the driver transistor 400. The bias current Ib2 may be supplied to the base of the driver transistor 400, and the driver transistor 400 may set a bias level (or bias point) by the bias current Ib2. A resistor R2 may be connected between the bias circuit 500 and the base of the driver transistor 400.

In the multi-stage power amplifier 1000b, the bias current Ib2 may be decreased by the over voltage protection circuit 300b. A current I_{CC2} flowing through the output terminal (i.e., collector) of the driver transistor 400 may be decreased when the bias current Ib2 is decreased.

The over voltage protection circuit 300b may detect a voltage of the input RF signal RFIN and be operated when the detected voltage has a set value or more. The over voltage protection circuit 300b may be connected to a terminal N2 of the bias circuit 500 and may sink a current Iₛᵢₙₖ from the terminal N2 when the detected voltage is the set value or more. The bias current Ib2 may be varied by the current Iₛᵢₙₖ. For example, the bias current Ib2 may be decreased when the current Iₛᵢₙₖ is increased, and here, the current I_{CC2} flowing through the driver transistor 400 may be decreased. The driver transistor 400 may thus be protected from an over voltage state.

An intermediate matching network may be connected to the output terminal (i.e., collector) of the driver transistor 400, and the intermediate matching network may perform impedance matching between the output RF signal of the driver transistor 400 and the power transistor 100.

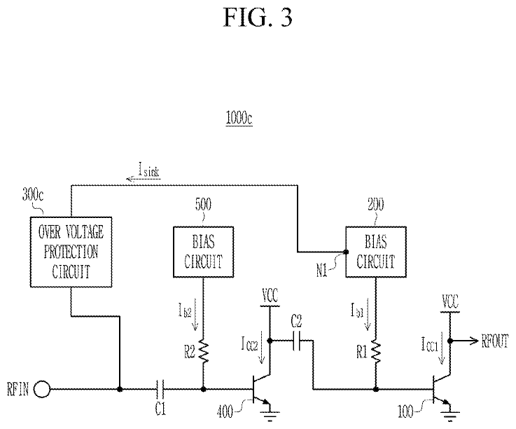

FIG. 3 is a view showing a power amplifier 1000c according to still another embodiment.

Referring to FIG. 3, the power amplifier 1000c may have a configuration similar to that of the multi-stage power amplifier 1000b of FIG. 2.

However, an over voltage protection circuit 300c may be connected to a terminal N1 of the bias circuit 200. The over voltage protection circuit 300c may detect a voltage of an input RF signal RFIN and sink a current Iₛᵢₙₖ from the terminal N1 when the detected voltage is a set value or more. The bias current Ib1 may be varied by the current Iₛᵢₙₖ. For example, the bias current Ib1 may be decreased when the current Iₛᵢₙₖ is increased, and here, a current I_{CC1} flowing through the power transistor 100 may be decreased.

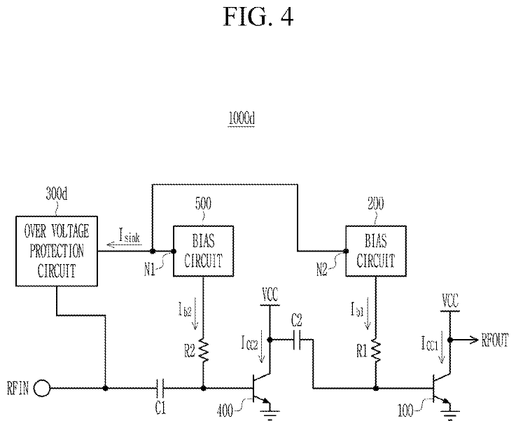

FIG. 4 is a view showing a power amplifier 1000d according to yet another embodiment.

Referring to FIG. 4, the power amplifier 1000d may have a configuration similar to that of the multi-stage power amplifier 1000b of FIG. 2.

However, an over voltage protection circuit 300d may be connected to a terminal N1 of a bias circuit 500. The over voltage protection circuit 300d may detect a voltage of an input RF signal RFIN and sink a current Iₛᵢₙₖ from the terminal N1 and a terminal N2 when the detected voltage has a set value or more. A bias current Ib1 and a bias current Ib2 may be varied by the current Iₛᵢₙₖ. For example, the bias current Ib1 and the bias current Ib2 may be decreased when the current Iₛᵢₙₖ is increased, and here, a current I_{CC1} flowing through the power transistor 100 and a current I_{CC2} flowing through the driver transistor 400 may be decreased.

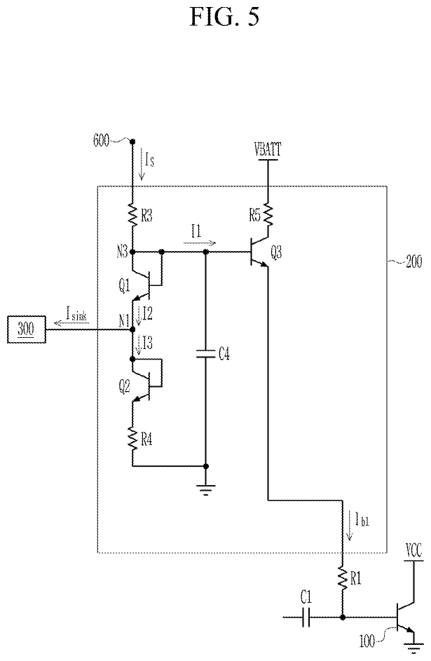

FIG. 5 is a view showing an example of the bias circuit 200 shown in FIG. 1.

Referring to FIG. 5, the bias circuit 200 may include a transistor Q1, a transistor Q2, a transistor Q3, a resistor R3, a resistor R4, a resistor R5, and a capacitor C4.

The transistors Q1, Q2, and Q3 may be implemented as the various transistors such as the heterojunction bipolar transistor HBT, the bipolar junction transistor BJT, and the insulated gate bipolar transistor IGBT. In addition, FIG. 5 shows that each of the transistors Q1, Q2, and Q3 is the n-type, which may be replaced by the p-type.

A node N1 may be a junction between an emitter of the transistor Q1 and a collector of the transistor Q2.

The base and collector of the transistor Q1 may each be connected to a node N3, and the collector of the transistor Q1 may be connected to a current source 600 supplying a reference current Is. The transistor Q1 may have a diode connection structure. The resistor R3 may be connected between the collector of the transistor Q1 and the current source 600.

The base and collector of the transistor Q2 may be connected to each other, and the collector of the transistor Q2 may be connected to the emitter of the transistor Q1. The transistor Q2 may have the diode connection structure, and an emitter of the transistor Q2 may be connected to the ground. The resistor R4 may be additionally connected between the emitter of the transistor Q2 and the ground.

A collector of the transistor Q3 may be connected to a power supply voltage VBATT. The resistor R5 may be additionally connected between the collector of the transistor Q3 and the power supply voltage VBATT. A base of the transistor Q3 may be connected to the node N3. In addition, an emitter of the transistor Q3 may be connected to the input terminal of the power transistor 100, and the bias current Ib1 may be supplied to the power transistor 100. The power supply voltage VBATT may be a battery voltage supplied from a battery.

The capacitor C4 may be connected between the base of the transistor Q3 and the ground, and may serve to block an alternating current (AC) component from a current I1 flowing to the base of the transistor Q3.

FIG. 5 shows that I2 represents a current flowing through the transistor Q1, and I3 represents a current flowing through the transistor Q2. In addition, I1 represents the current flowing into the base of the transistor Q3.

The reference current Is, the current I1, and the current I2 may satisfy a relationship of Equation 1 below.

$$Is = I 1 + I 2 \qquad ( Equation 1 )$$

At the terminal N1, the current I2, the current Iₛᵢₙₖ, and the current I3 may satisfy a relationship of Equation 2 below.

$$I 2 = {I}_{sink} + I 3 \qquad ( Equation 2 )$$

In Equation 2, assuming that the current I3 has a fixed value, the current I2 may be increased when the current Iₛᵢₙₖ is increased. Referring to Equation 1, assuming that the reference current Is has a fixed value, the current I1 may be decreased when the current I2 is increased. The bias current Ib1 may be decreased when the current I1 is decreased. That is, the bias current Ib1 may be decreased when the current Iₛᵢₙₖ is increased.

The over voltage protection circuit 300a may detect a magnitude of the input RF signal RFIN and sink the current Iₛᵢₙₖ from the terminal N1 when the magnitude of the detected input RF signal RFIN is a set value or more.

As the current Iₛᵢₙₖ is increased, the bias current Ib1 may be decreased by the over voltage protection circuit 300a. The bias current Ib1 and the current I_{CC1} flowing through the power transistor 100 may have a relationship of Equation 3.

$$Ib 1 = \frac{{I}_{CC 1}}{β} \qquad ( Equation 3 )$$

Here, β may represent a common-emitter current gain of the power transistor 100.

Therefore, when the bias current Ib1 is decreased, the current I_{CC1} flowing through the power transistor 100 may be decreased. The power transistor 100 may thus be protected from the over voltage state.

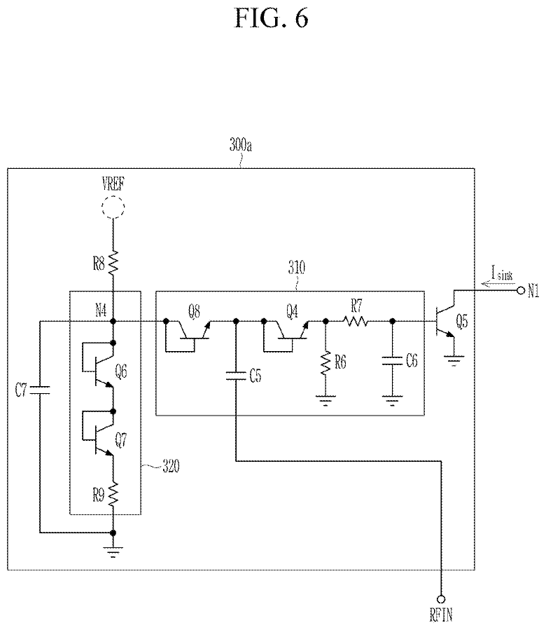

FIG. 6 is a view showing an example of the over voltage protection circuit 300a shown in FIG. 1.

Referring to FIG. 6, the over voltage protection circuit 300a may include an input signal detector 310, a resistor R8, and a sink transistor Q5.

The input signal detector 310 may detect the magnitude of the input RF signal RFIN. The input signal detector 310 may generate a turn-on voltage of the sink transistor Q5 based on the detected magnitude of the input RF signal RFIN, and apply the generated turn-on voltage to a base of the sink transistor Q5. The input signal detector 310 may generate the turn-on voltage of the sink transistor Q5 when the magnitude of the detected input RF signal RFIN is the set value or more, and generate a turn-off voltage of the sink transistor Q5 when the magnitude of the detected input RF signal RFIN has less than the set value.

The input signal detector 310 may include a capacitor C5, a transistor Q4, a transistor Q8, a resistor R6, a resistor R7, and a capacitor C6.

The RF signal RFIN may be input to one end of the capacitor C5. The other end of the capacitor C5 may be connected to a collector of the transistor Q4 and an emitter of the transistor Q8. The capacitor C5 may perform the function of blocking the direct current (DC) component from the RF signal RFIN.

The base and collector of the transistor Q8 may be connected to each other, and the transistor Q8 may have the diode connection structure. That is, the transistor Q8 may be a diode.

The resistor R8 may be connected between a reference voltage source supplying a reference voltage VREF and the collector of the transistor Q8.

The base and collector of the transistor Q4 may be connected to each other, and the transistor Q4 may have the diode connection structure. That is, the transistor Q4 may be the diode. An emitter of the transistor Q4 may be connected to one end of the resistor R6 and one end of the resistor R7. The other end of the resistor R6 may be connected to the ground, and the other end of the resistor R7 may be connected to the base of the sink transistor Q5 and one end of the capacitor C6. The other end of the capacitor C6 may be connected to the ground. One end of the capacitor C5 may be an input terminal of the input signal detector 310, and the other end of the resistor R7 or one end of the capacitor C6 may be an output terminal of the input signal detector 310. The capacitor C6 may perform a function of smoothing an input voltage.

A signal input to the capacitor C5 may be the RF signal RFIN, and a voltage of the capacitor C5 may be changed based on a period.

When the voltage of the RF signal RFIN input to the capacitor C5 is a negative voltage, the transistor Q8 may be turned on and the transistor Q4 may be turned off, and the current may thus flow from the reference voltage source supplying the reference voltage VREF to the capacitor C5, and the capacitor C5 may be charged with a voltage corresponding to the reference voltage VREF. The voltage corresponding to the reference voltage VREF may be a voltage generated while the current passes through the resistor R8 and the transistor Q8 from the reference voltage supply source.

When the voltage of the RF signal RFIN input to the capacitor C5 is a positive voltage, the transistor Q8 may be turned off and the transistor Q4 may be turned on. The voltage charged in the capacitor C5 may then be divided by the resistors R6 and R7, and the divided voltage may then be charged in the capacitor C6. Here, the voltage charged in the capacitor C5 may be the sum of the voltages charged in the capacitor C5 when the voltage of the input RF signal RFIN is the positive voltage and the voltage corresponding to the reference voltage VREF when the RF signal RFIN is the negative voltage. In this way, the input signal detector 310 may detect the magnitude of the RF signal RFIN, and the magnitude of the RF signal RFIN may correspond to an envelope of the RF signal RFIN.

The sink transistor Q5 may be turned on when the voltage charged in the capacitor C6, i.e., the voltage divided by the resistors R6 and R7, is applied to the base of the sink transistor Q5, and the voltage applied to the base of the sink transistor Q5 is the turn-on voltage of the sink transistor Q5.

When Vb is the voltage applied to the base of the sink transistor Q5 by the input signal detector 310, Vb may be expressed approximately as in Equation 4.

$$Vb = A \times ( {VREF}^{′} - ( 2 \times VF ) ) \times B \qquad ( Equation 4 )$$

Here, A may represent the magnitude of the RF signal RFIN, and B may represent a voltage division coefficient by the resistors R6 and R7. In addition, VF may represent a turn-on voltage between the transistor Q4 and the transistor Q8, and VREF′ may represent the voltage charged in the capacitor C5 when the voltage of the RF signal RFIN is the negative voltage, the transistor Q8 is turned on, and the transistor Q4 is turned off.

According to Equation 4, when the magnitude of the RF signal RFIN is the set value or more, the sink transistor Q5 may be turned on by the voltage divided by the resistors R6 and R7. When the magnitude of the RF signal RFIN is less than the set value, the sink transistor Q5 may be turned off. Through Equation 4, when the magnitude of the RF signal RFIN is the set value, the turn-on voltage of the sink transistor Q5 may be set for the sink transistor Q5 to be turned on.

The sink transistor Q5 may sink the current Iₛᵢₙₖ from the terminal N1 of the bias circuit 200 when the magnitude of the RF signal RFIN is the set value or more.

A collector of the sink transistor Q5 may be connected to the terminal N1 of the bias circuit 200, and the base of the sink transistor Q5 may be connected to the output terminal of the input signal detector 310. An emitter of the sink transistor Q5 may be connected to the ground. Here, Iₛᵢₙₖ may represent the current flowing through the collector of the sink transistor Q5. The sink transistor Q5 may generate the current Iₛᵢₙₖ in response to the voltage applied through its base.

The current Iₛᵢₙₖ may be generated when the sink transistor Q5 is turned on. The current Iₛᵢₙₖ may be increased when the voltage applied through the base of the sink transistor Q5 is increased. According to the relationships of Equations 1 and 2, the bias current Ib1 may be decreased as the current Iₛᵢₙₖ is increased.

When the input RF signal RFIN is increased, a magnitude value of the input RF signal RFIN detected by the input signal detector 310 may be increased, and more current may be transferred to the base of the sink transistor Q5. The current Iₛᵢₙₖ that is sinked by the sink transistor Q5 may also be increased when the sink transistor Q5 is turned on and the current applied through the base of the sink transistor Q5 is increased. According to the relationships of Equations 1 and 2, the bias current Ib1 may be decreased as the current Iₛᵢₙₖ is increased. That is, the over voltage protection circuit 300a may protect the power transistor 100 by sinking the current Iₛᵢₙₖ from the terminal N1 when the magnitude value of the input RF signal RFIN is the set value or more.

The over voltage protection circuit 300a may further include a temperature compensation circuit 320 and a bypass capacitor C7.

The temperature compensation circuit 320 may serve to reduce a temperature deviation in the voltage applied to the base of the sink transistor Q5. The temperature compensation circuit 320 may include a transistor Q6, a transistor Q7, and the resistor R8.

The base and collector of the transistor Q6 may be connected to each other, and the collector of the transistor Q6 may be connected to the reference voltage source supplying the reference voltage VREF through the resistor R8. The transistor Q6 may have the diode connection structure. The transistor Q6 may be the diode. In FIG. 6, the collector of the transistor Q6 is represented by a node N4.

The base and collector of the transistor Q7 may be connected to each other, and the collector of the transistor Q7 may be connected to an emitter of the transistor Q6. An emitter of the transistor Q7 may be connected to the ground through a resistor R9. The transistor Q7 may have the diode connection structure. The transistor Q7 may be the diode.

The transistors Q6 or the transistor Q7 may have the same temperature coefficient as that of the transistors Q4 or the transistor Q8.

When the temperature is changed, the turn-on voltage between the base and the emitter of the transistor Q8 and the transistor Q4 may be changed. When the temperature is increased, the turn-on voltage between the base and the emitter of the transistor Q8 and the transistor Q4 may be decreased, and when the temperature is decreased, the turn-on voltage between the base and the emitter of the transistor Q8 and the transistor Q4 may be increased.

That is, referring to Equation 4, VF, which is the turn-on voltage between the transistor Q8 and the transistor Q4, may have the temperature deviation. When VF is changed, the voltage Vb that is applied to the base of the sink transistor Q5 by the input signal detector 310 may also be changed. Here, the transistors Q6 and Q7 of the temperature compensation circuit 320 may have the same temperature dependence as that of the transistors Q8 and Q4, and a VREF′ may thus vary based on the temperature by the transistors Q6 and Q7. VREF′ may be decreased when the temperature is increased, and VREF′ may be increased when the temperature is decreased.

That is, the temperature compensation circuit 320 can lower the temperature deviation in the base voltage of the sink transistor Q5 by allowing VREF′ to be also changed through the transistors Q6 and Q7 when VF, which is the turn-on voltage between the base and the emitter of the transistor Q8 and the transistor Q4 based on the temperature change, is changed.

In addition, the bypass capacitor C7 may be connected between the node N4 and the ground. The bypass capacitor C7 may be used to block the alternating current (AC) component from a voltage of the node N4.

In the over voltage protection circuit 300, the transistors Q4 to Q8 may each be implemented as the various transistors such as the heterojunction bipolar transistor HBT, the bipolar junction transistor BJT, and the insulated gate bipolar transistor IGBT. In addition, FIG. 6 shows that each of the transistors Q4 to Q8 is an npn-type, which may be replaced by a pnp-type.

In addition, the over voltage protection circuit 300a shown in FIG. 6 may be equally applied to the over voltage protection circuit 300c shown in FIG. 3.

Meanwhile, FIG. 6 shows that the collector of the sink transistor Q5 is connected to a node N1. However, the collector of the sink transistor Q5 may be connected to the node N3 of the bias circuit 200 shown in FIG. 5.

In a case where the collector of the sink transistor Q5 is connected to the node N3 of the bias circuit 200 shown in FIG. 5, the over voltage protection circuit 300a may detect the magnitude of the input RF signal RFIN, and sink the current Iₛᵢₙₖ from the node N3 when the magnitude value of the detected input RF signal RFIN is the set value or more. The sink transistor Q5 may be turned on when the magnitude value of the input RF signal RFIN is the set value or more. The current Iₛᵢₙₖ may be generated when the sink transistor Q5 is turned on. Assuming that the reference current Is and the current I2 have fixed values, the current I1 may be decreased and the bias current Ib1 may also be decreased as the current Iₛᵢₙₖ is generated. That is, even the case where the collector of the sink transistor Q5 is connected to the node N3 of the bias circuit 200 shown in FIG. 5 may have the same or similar effect as the case where the collector of the sink transistor Q5 is connected to the node N1 of the bias circuit 200.

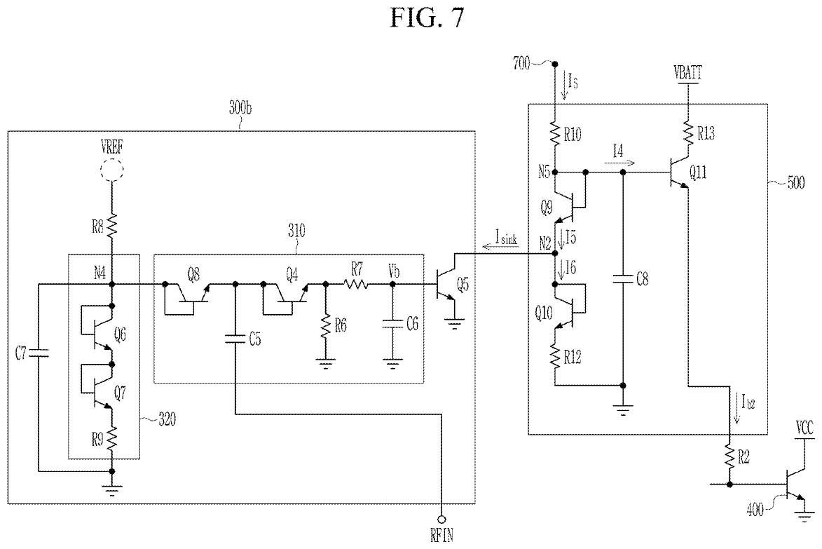

FIG. 7 is a view showing examples of the bias circuit 500 and the over voltage protection circuit 300b shown in FIG. 2.

Referring to FIG. 7, the over voltage protection circuit 300b may have a configuration similar to that of the over voltage protection circuit 300a shown in FIG. 6. However, the collector of the sink transistor Q5 may be connected to a node N2 of the bias circuit 500.

The bias circuit 500 may supply the bias current Ib2 to the driver transistor 400. The bias circuit 500 may have a configuration similar to that of the bias circuit 200 shown in FIG. 5.

The bias circuit 500 may include a transistor Q9, a transistor Q10, a transistor Q11, a resistor R10, a resistor R11, a resistor R12, and a capacitor C8.

N2 may be a junction between an emitter of the transistor Q9 and a collector of the transistor Q10. In FIG. 7, a node N5 may represent a junction between the base and collector of the transistor Q9.

The transistors Q9, Q10, and Q11 may be implemented as the various transistors such as the heterojunction bipolar transistor HBT, the bipolar junction transistor BJT, and the insulated gate bipolar transistor IGBT. In addition, FIG. 7 shows that each of the transistors Q9, Q10, and Q11 is an n-type, which may be replaced by a p-type.

The base and collector of the transistor Q9 may each be connected to a node N5, and the collector of the transistor Q9 may be connected to a current source 700 supplying a reference current Is. The emitter of the transistor Q9 may be connected to the node N2. The transistor Q9 may have a diode connection structure. The resistor R10 may be connected between the collector of the transistor Q9 and the current source 700.

The base and collector of the transistor Q10 may be connected to each other, and the collector of the transistor Q10 may be connected to the node N2. Here, Vc may represent a collector voltage of the transistor Q10 that corresponds to a voltage of the node N2. The transistor Q10 may have the diode connection structure, and an emitter of the transistor Q10 may be connected to the ground. The resistor R12 may be additionally connected between the emitter of the transistor Q10 and the ground.

A collector of the transistor Q11 may be connected to a power supply voltage VBATT. The resistor R13 may be additionally connected between the collector of the transistor Q11 and the power supply voltage VBATT. A base of the transistor Q11 may be connected to the node N5. In addition, an emitter of the transistor Q5 may be connected to the input terminal of the driver transistor 400, and the bias current Ib2 flowing through the emitter of the transistor Q5 may be supplied to the driver transistor 400. The power supply voltage VBATT may be a battery voltage supplied from a battery.

The capacitor C8 may be connected between the base of the transistor Q11 and the ground, and may serve to block the alternating current (AC) component from a current I4 flowing to the base of the transistor Q11.

FIG. 7 shows that I5 represents a current flowing through the transistor Q9, and I6 represents a current flowing through the transistor Q10. In addition, I4 represents the current flowing into the base of the transistor Q11.

The reference current Is, the current I4, and the current I5 may satisfy a relationship of Equation 5 below.

$$Is = I 4 + I 5 \qquad ( Equation 5 )$$

At the terminal N2, the current I5, the current Iₛᵢₙₖ, and the current I6 may satisfy a relationship of Equation 6 below.

$$I 5 = {I}_{sink} + I 6 \qquad ( Equation 6 )$$

In Equation 6, assuming that the current I6 is a fixed value, the current I5 may be increased when the current Iₛᵢₙₖ is increased. Referring to Equation 5, assuming that the reference current Is has a fixed value, the current I4 may be decreased when the current I5 is increased. The bias current Ib2 may be decreased when the current I4 is decreased. That is, the bias current Ib2 may be decreased when the current Iₛᵢₙₖ is increased.

The over voltage protection circuit 300b may detect a magnitude of the input RF signal RFIN and sink the current Iₛᵢₙₖ from the terminal N2 when the magnitude of the detected input RF signal RFIN has a set value or more. The magnitude of the input RF signal RFIN may be divided by resistors R6 and R7, and the voltage divided by the resistors R6 and R7 may be applied to a base of the sink transistor Q5. FIG. 7 shows that Vb represents a voltage applied to the base of the sink transistor Q5. When the magnitude of the RF signal RFIN is the set value or more, the sink transistor Q5 may be turned on by the voltage Vb divided by the resistors R6 and R7.

The bias current Ib2 may be decreased as the current Iₛᵢₙₖ is increased when the sink transistor Q5 is turned on. The bias current Ib2 and the current I_{CC2} flowing through the bias current Ib2 and the driver transistor 400 may have a relationship of Equation 7.

$$Ib 2 = \frac{{I}_{CC 2}}{β} \qquad ( Equation 7 )$$

Here, β may represent a common-emitter current gain of the driver transistor 400.

Therefore, when the bias current Ib2 is decreased, the current I_{CC2} flowing through the driver transistor 400 may be decreased. The driver transistor 400 may thus be protected from the over voltage state.

Meanwhile, FIG. 7 shows that the collector of the sink transistor Q5 is connected to the node N2. However, the collector of the sink transistor Q5 may be connected to the node N5.

In a case where the collector of the sink transistor Q5 is connected to the node N5, the over voltage protection circuit 300b may detect the magnitude of the input RF signal RFIN, and sink the current Iₛᵢₙₖ from the node N5 when a magnitude value of the detected input RF signal RFIN is the set value or more. The sink transistor Q5 may be turned on when the magnitude value of the input RF signal RFIN is the set value or more. The current Iₛᵢₙₖ may be generated when the sink transistor Q5 is turned on. Assuming that the current I5 and the reference current Is have fixed values, the current I4 may be decreased and the bias current Ib2 may also be decreased as the current Iₛᵢₙₖ is generated.

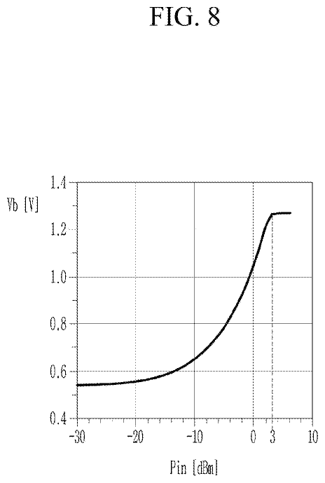

FIG. 8 is a view showing simulation results of the base voltage of the sink transistor Q5 and the power of the input RF signal, shown in FIG. 7.

In FIG. 8, a horizontal axis may represent the power of the input RF signal RFIN, and a vertical axis may represent the base voltage Vb of the sink transistor Q5.

Referring to FIG. 8, when power Pin of the input RF signal RFIN becomes 3 dBm, the sink transistor Q5 may be turned on by the base voltage Vb applied to the sink transistor Q5. In addition, even though the power Pin of the input RF signal RFIN is more than 3 dBm, the base voltage Vb of the sink transistor Q5 may be maintained constant, and the sink transistor Q5 may thus be maintained in a turn-on state.

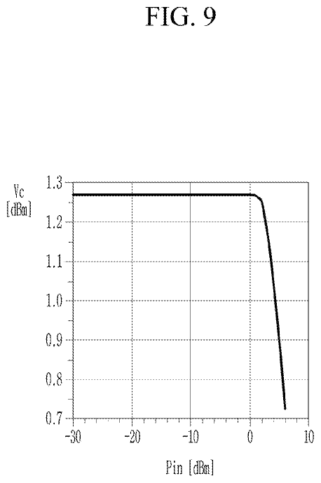

FIG. 9 is a view showing simulation results of a collector voltage of the transistor Q10 and the power of the input RF signal shown in FIG. 7.

In FIG. 9, a horizontal axis may represent the power Pin of the input RF signal RFIN, and a vertical axis may represent the collector voltage Vc of the transistor Q10.

Referring to FIG. 9, when receiving the input RF signal RFIN having the power Pin of 3 dBm or more, the sink transistor Q5 may be turned on to generate the current Iₛᵢₙₖ. Accordingly, it may be seen that the collector voltage Vc of the transistor Q10 is lower in the input RF signal RFIN having the power Pin of 3 dBm or more.

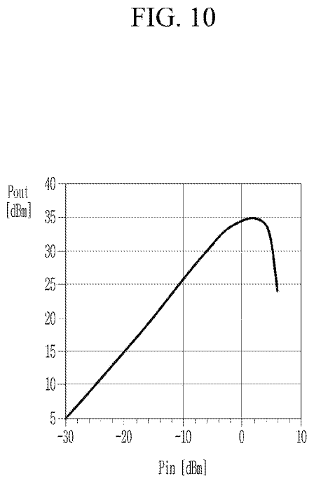

FIG. 10 is a view showing simulation results of the input RF signal RFIN and output RF signal RFOUT of the multi-stage power amplifier shown in FIG. 2.

In FIG. 10, a horizontal axis may represent the power Pin of the input RF signal RFIN, and a vertical axis may represent power Pout of the output RF signal RFOUT of the multi-stage power amplifier 1000b.

Referring to FIG. 10, it may be seen that the power Pout of the output RF signal RFOUT of the multi-stage power amplifier 1000b is decreased when the power Pin of the input RF signal RFIN is increased to be 3 dBm or more.

That is, when receiving the input RF signal RFIN having the power Pin of 3 dBm or more, the over voltage protection circuit 300b may be operated to decrease the bias current Ib2 of the bias circuit 500. Accordingly, the power Pout of the output RF signal RFOUT of the multi-stage power amplifier 1000b may be decreased, thus protecting the multi-stage power amplifier 1000b.

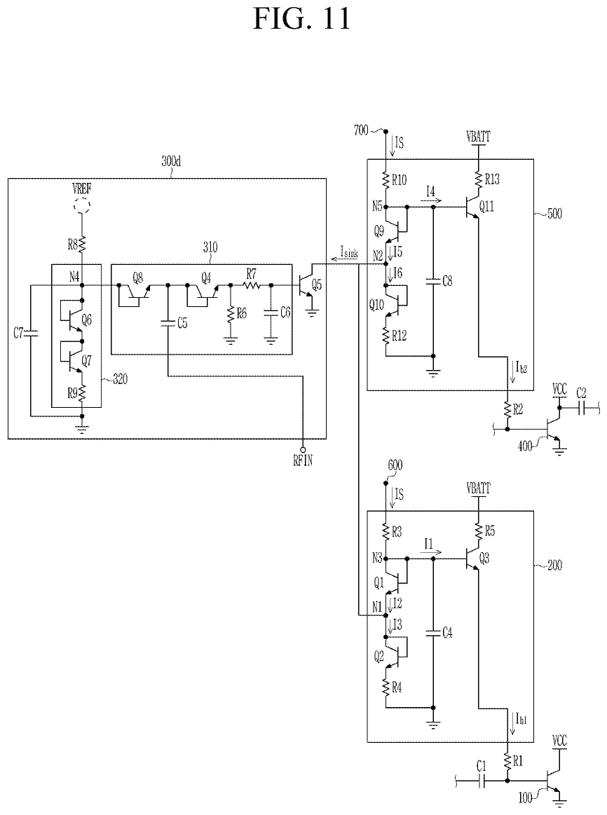

FIG. 11 is a view showing the over voltage protection circuit 300d shown in FIG. 4.

Referring to FIG. 11, the over voltage protection circuit 300d may have a configuration similar to that of the over voltage protection circuit 300a shown in FIG. 6. However, the collector of the sink transistor Q5 may be connected to both the node N1 of the bias circuit 200 and the node N2 of the bias circuit 500.

When receiving the input RF signal RFIN having high power, the sink transistor Q5 in the over voltage protection circuit 300d may be turned on. When the sink transistor Q5 is turned on, the current Iₛᵢₙₖ may be sinked from the node N1 of the bias circuit 200 and the node N2 of the bias circuit 500. Accordingly, the bias current Ib2 applied to the base of the driver transistor 400 and the bias current Ib1 applied to the base of the power transistor 100 may be simultaneously decreased.

However, the collector of the sink transistor Q5 may be connected to both the node N3 of the bias circuit 200 and the node N5 of the bias circuit 500.

According to at least one of the embodiments, the power amplifier may be protected by detecting the envelope of the RF signal input to the power amplifier, thus controlling the bias current applied to the power amplifier.

While specific examples have been shown and described above, it will be apparent after an understanding of this disclosure that various changes in form and details may be made in these examples without departing from the spirit and scope of the claims and their equivalents.

The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An over voltage protection circuit protecting a power amplifier amplifying an input radio frequency (RF) signal by receiving a bias current from a bias circuit, the circuit comprising:
an input signal detector detecting a magnitude of the input RF signal; and
a first transistor receiving the magnitude of the input RF signal through a control terminal thereof and turned on based on the magnitude of the input RF signal to sink the current from a first node of the bias circuit.

2. The circuit of claim 1, wherein
the bias circuit comprises:
a second transistor and a third transistor stacked between a current source supplying a reference current and the ground; and
a fourth transistor having a control terminal connected to the current source and supplying the bias current, and
the first node is a junction between the second transistor and the third transistor.

3. The circuit of claim 1, wherein
the bias circuit comprises a second transistor supplying the bias current, and
the first node is a control terminal of the second transistor.

4. The circuit of claim 1, wherein
the input signal detector comprises a first resistor adjusting a turn-on voltage level of the first transistor based on the magnitude of the input RF signal.

5. The circuit of claim 4, wherein
the input signal detector further comprises:
a capacitor having one end into which the input RF signal is input;
a diode connected between the other end of the capacitor and one end of the first resistor; and
a second resistor connected between the one end of the first resistor and the ground, and
the other end of the first resistor is connected to the control terminal of the first transistor.

6. The circuit of claim 1, wherein
the magnitude of the input RF signal corresponds to an envelope of the input RF signal.

7. The circuit of claim 1, wherein
the power amplifier comprises a power transistor amplifying and outputting a voltage of the input RF signal, and
the bias circuit supplies the bias current to the power transistor.

8. The circuit of claim 1, wherein
the power amplifier comprises:
a driver transistor receiving a first bias current and amplifying a voltage of the input RF signal; and
a power transistor receiving a second bias current and amplifying an output RF signal of the driver transistor,
the bias circuit comprises:
a first bias circuit supplying the first bias current; and
a second bias circuit supplying the second bias current, and
the first transistor is turned on based on the magnitude of the input RF signal to sink the current from at least one of a first node of the first bias circuit and a first node of the second bias circuit.

9. The circuit of claim 8, wherein
the first bias circuit comprises:
a second transistor and a third transistor stacked between a current source supplying a reference current and the ground; and
a fourth transistor having a control terminal connected to the current source and supplying the first bias current,
the second bias circuit comprises:
a fifth transistor and a sixth transistor stacked between a current source supplying the reference current and the ground; and
a seventh transistor having a control terminal connected to the current source and supplying the first bias current,
the first node of the first bias circuit is a junction between the second transistor and the third transistor,
the first node of the second bias circuit is a junction between the fifth transistor and the sixth transistor, and
a first terminal of the first transistor is connected to at least one of the first node of the first bias circuit and the first node of the second bias circuit, and a second terminal of the first transistor is connected to the ground.

10. The circuit of claim 8, wherein
the first bias circuit comprises a second transistor supplying the first bias current,
the second bias circuit comprises a third transistor supplying the second bias current,
the first node of the first bias circuit is a control terminal of the second transistor,
the first node of the second bias circuit is a control terminal of the third transistor, and
a first terminal of the first transistor is connected to at least one of the first node of the first bias circuit and the first node of the second bias circuit, and a second terminal of the first transistor is connected to the ground.

11. A power amplifier comprising:
a first transistor amplifying a radio frequency (RF) signal;
a first bias circuit supplying a first bias current to the first transistor; and
an over voltage protection circuit detecting a magnitude of the input RF signal and decreasing the first bias current by sinking the current from the first bias circuit when the magnitude of the input RF signal is a set value or more.

12. The power amplifier of claim 11, wherein
the over voltage protection circuit comprises:
an input signal detector detecting the magnitude of the input RF signal; and
a second transistor receiving the magnitude of the input RF signal through a control terminal thereof and sinking the current from the first bias circuit when turned on.

13. The power amplifier of claim 12, wherein
the first bias circuit comprises:
a third transistor and a fourth transistor stacked between a current source supplying a reference current and the ground; and
a fifth transistor having a control terminal connected to the current source and supplying the first bias current, and
a first terminal of the second transistor is connected to a junction between the third transistor and the fourth transistor, and a second terminal of the second transistor is connected to the ground.

14. The power amplifier of claim 12, wherein
the first bias circuit comprises a third transistor supplying the first bias current, and
a first terminal of the second transistor is connected to a control terminal of the third transistor, and a second terminal of the second transistor is connected to the ground.

15. The power amplifier of claim 12, further comprising
a third transistor amplifying an output RF signal of the first transistor, and
a second bias circuit supplying a second bias current to the third transistor.

16. The power amplifier of claim 15, wherein
the over voltage protection circuit sinks the current from the second bias circuit when the magnitude of the input RF signal is the set value or more.

17. The power amplifier of claim 11, wherein
the magnitude of the input RF signal corresponds to an envelope of the input RF signal.

18. A power amplifier comprising:
one or more transistors configured to amplify an input radio frequency (RF) signal and to each receive a bias current of one or more bias currents; and
an over voltage protection circuit configured to detect a magnitude of the input RF signal and to decrease at least one of the one or more bias currents in response to the detected magnitude of the input RF signal.

19. The power amplifier of claim 18, further comprising one or more bias circuits configured to supply the one or more bias currents,
wherein the over voltage protection circuit is further configured to sink the bias current from the one or more bias circuits to decrease the at least one of the one or more bias currents.

20. The power amplifier of claim 19, wherein the over voltage protection circuit comprises:
a sink transistor configured to turn on to decrease the at least one of the one or more bias currents; and
a resistor configured to adjust a turn on voltage of the sink transistor.
